(19) United States
(12) Patent Application Publication
(10) Pub. No.: US 2026/0142258 A1
(43) Pub. Date: May 21, 2026

(54) FLEXIBLE WIRING COMPONENT AND CONDUCTIVE MODULE

(71) Applicant: YAZAKI CORPORATION, Tokyo (JP)

(72) Inventor: Mariko Nakagawa, Makinohara-shi (JP)

(21) Appl. No.: 19/390,724

(22) Filed: Nov. 17, 2025

(30) Foreign Application Priority Data
Nov. 18, 2024 (JP) 2024-200836

(51) Int. Cl. H01M 10/48; H01M 10/42; H05K 1/02

(52) U.S. Cl. CPC H01M 10/48; H01M 10/4257; H05K 1/0277; H01M 2220/20

(57) ABSTRACT

A wiring main body of a flexible wiring component includes a slit cut out in an array direction from one end to another end in the array direction, a first branch wiring portion on a side of a first electrode terminal group, a second branch wiring portion on a side of a second electrode terminal group, and a coupling wiring portion that performs coupling thereof on a side of another end in the array direction. The first branch wiring portion includes a first inclined side portion that is a side portion on a side of the first electrode terminal group, the side portion being continuous with an end portion on the side of the first electrode terminal group in the coupling wiring portion. The second branch wiring portion includes a second inclined side portion that is a side portion on a side of the second electrode terminal group.

### CROSS-REFERENCE TO RELATED APPLICATION(S)

The present application claims priority to and incorporates by reference the entire contents of Japanese Patent Application No. 2024-200836 filed in Japan on Nov. 18, 2024.

### BACKGROUND OF THE INVENTION

### 1. Field of the Invention

The present invention relates to a flexible wiring component and a conductive module.

### 2. Description of the Related Art

Conventionally, a battery module in which a plurality of battery cells is arrayed, and a conductive module that electrically connects the battery module and a battery monitoring unit are mounted in a vehicle including a rotary machine as a driving source (such as a battery electric vehicle (BEV) or a hybrid electric vehicle (HEV)). The conductive module includes a bus bar that is physically and electrically connected to electrode terminals of the battery cells, and a flexible wiring component such as a flexible printed circuit (FPC) that electrically connects the bus bar and the battery monitoring unit. Here, in the battery module, there are two rows of assemblies (electrode terminal groups) of a plurality of electrode terminals lined up in an array direction of the plurality of battery cells. In the flexible wiring component, a routing portion extending in the array direction of the plurality of battery cells is provided for each of the electrode terminal groups. One routing portion is routed along the plurality of electrode terminals of the one electrode terminal group, and is electrically connected to the bus bar connected to the electrode terminals of the one electrode terminal group. The other routing portion is routed along the plurality of electrode terminals of the other electrode terminal group, and is electrically connected to the bus bar connected to the electrode terminals of the other electrode terminal group. Such a flexible wiring component is disclosed in, for example, Japanese Patent No. JP 7 536 461 B.

Incidentally, this type of flexible wiring component is formed by, for example, die cutting of a plurality of pieces from one rectangular sheet serving as a base material. This flexible wiring component is formed to have a rectangular shape extending in an array direction of a plurality of battery cells and to have a slit cut out in a rectangular shape from a center of one end toward a center of the other end in the array direction. As a result, in the flexible wiring component, rectangular routing portions respectively for electrode terminal groups are formed with the slit being interposed therebetween. Each of the routing portions is bent twice on a root side and is made close to the electrode terminal group. In this conventional flexible wiring component, a shape of an outer peripheral edge at the time of die cutting is a rectangular shape, and a yield in one rectangular sheet is taken into consideration. However, it is desired to extract more flexible wiring components from one sheet and to improve the yield.

### SUMMARY OF THE INVENTION

Thus, an object of the present invention is to provide a flexible wiring component and a conductive module suitable for improving a yield.

A flexible wiring component according to one aspect of the present invention is a voltage detection line group electrically connecting a battery module and a battery monitoring unit and covered with insulation coating, a plurality of battery cells being arrayed in a row in the battery module, the battery monitoring unit monitoring a battery state of each of the battery cells, the flexible wiring component being formed as a flexible flat wiring main body extending in an array direction of the plurality of battery cells, wherein one each of positive and negative electrode terminals are provided at an interval in a cell body in each of the battery cells, the battery module includes a first electrode terminal group in which one of the electrode terminals in each of the battery cells is lined up in the array direction, and a second electrode terminal group in which another one of the electrode terminals in each of the battery cells is lined up in the array direction, the voltage detection line group includes a plurality of first voltage detection lines electrically connecting the electrode terminals of the first electrode terminal group and the battery monitoring unit, and a plurality of second voltage detection lines electrically connecting the electrode terminals of the second electrode terminal group and the battery monitoring unit, the wiring main body includes a linear or rectangular slit cut out in the array direction from one end to another end in the array direction, a first branch wiring portion that extends in the array direction on a side of the first electrode terminal group compared to the slit, and in which the plurality of first voltage detection lines is routed, a second branch wiring portion that extends in the array direction on a side of the second electrode terminal group compared to the slit and in which the plurality of second voltage detection lines is arranged, and a coupling wiring portion that couples the first branch wiring portion and the second branch wiring portion on a side of the other end in the array direction and electrically connects the plurality of first voltage detection lines and the plurality of second voltage detection lines to the battery monitoring unit, the first branch wiring portion includes a first inclined side portion that is a side portion on a side of the first electrode terminal group, the side portion being continuous with an end portion on the side of the first electrode terminal group in the coupling wiring portion, and that gradually approaches the slit from the side of the other end in the array direction toward the side of the one end in the array direction, the second branch wiring portion includes a second inclined side portion that is a side portion on a side of the second electrode terminal group, the side portion being continuous with an end portion on the side of the second electrode terminal group in the coupling wiring portion, and that gradually approaches the slit from the side of the other end in the array direction toward the side of the one end in the array direction, and the first inclined side portion and the second inclined side portion are inclined at a same angle in the array direction.

A conductive module according to another aspect of the present invention includes a flexible wiring component; a first inter-terminal connection component; a second inter-terminal connection component; a first intermediate connection component; and a second intermediate connection component, wherein the flexible wiring component is a voltage detection line group electrically connecting a battery module and a battery monitoring unit and covered with insulation coating, a plurality of battery cells being arrayed in a row in the battery module, the battery monitoring unit monitoring a battery state of each of the battery cells, the flexible wiring component being formed as a flexible flat wiring main body extending in an array direction of the plurality of battery cells, one each of positive and negative electrode terminals are provided at an interval in a cell body in each of the battery cells, the battery module includes a first electrode terminal group in which one of the electrode terminals in each of the battery cells is lined up in the array direction, and a second electrode terminal group in which another one of the electrode terminals in each of the battery cells is lined up in the array direction, the first inter-terminal connection component is provided for every pair of the electrode terminals adjacent in the array direction in the first electrode terminal group and electrically connects the pair of electrode terminals, the second inter-terminal connection component is provided for every pair of the electrode terminals adjacent in the array direction in the second electrode terminal group and electrically connects the pair of electrode terminals, the voltage detection line group includes a first voltage detection line that is provided for each of the first inter-terminal connection components and electrically connects the first inter-terminal connection component and the battery monitoring unit, and a second voltage detection line that is provided for each of the second inter-terminal connection components and that electrically connects the second inter-terminal connection component and the battery monitoring unit, the first intermediate connection component is provided for each of the first voltage detection lines, and is physically and electrically connected to a pair of the first voltage detection line and the first inter-terminal connection component, the second intermediate connection component is provided for each of the second voltage detection lines, and is physically and electrically connected to a pair of the second voltage detection line and the second inter-terminal connection component, the wiring main body includes a linear or rectangular slit cut out in the array direction from one end to another end in the array direction, a first branch wiring portion that extends in the array direction on a side of the first electrode terminal group compared to the slit, and in which a plurality of the first voltage detection lines is routed, a second branch wiring portion that extends in the array direction on a side of the second electrode terminal group compared to the slit and in which a plurality of the second voltage detection lines is routed, and a coupling wiring portion that couples the first branch wiring portion and the second branch wiring portion on a side of the other end in the array direction and electrically connects the plurality of first voltage detection lines and the plurality of second voltage detection lines to the battery monitoring unit, the first branch wiring portion includes a first inclined side portion that is a side portion on a side of the first electrode terminal group, the side portion being continuous with an end portion on the side of the first electrode terminal group in the coupling wiring portion, and that gradually approaches the slit from the side of the other end in the array direction toward a side of the one end in the array direction, the second branch wiring portion includes a second inclined side portion that is a side portion on a side of the second electrode terminal group, the side portion being continuous with an end portion on the side of the second electrode terminal group in the coupling wiring portion, and that gradually approaches the slit from the side of the other end in the array direction toward the side of the one end in the array direction, and the first inclined side portion and the second inclined side portion are inclined at a same angle in the array direction.

The above and other objects, features, advantages and technical and industrial significance of this invention will be better understood by reading the following detailed description of presently preferred embodiments of the invention, when considered in connection with the accompanying drawings.

### BRIEF DESCRIPTION OF THE DRAWINGS

FIG. 1 is a view illustrating a flexible wiring component and a conductive module according to an embodiment which component and module are installed in a battery module;

FIG. 2 is a view illustrating a flexible wiring component after die cutting;

FIG. 3 is an explanatory view for describing a flexible wiring component according to the embodiment before die cutting in a sheet-like base material;

FIG. 4 is an explanatory view for describing a conventional flexible wiring component before die cutting in a sheet-like base material; and

FIG. 5 is an explanatory view for describing a mounting area of the flexible wiring component and the conductive module according to the embodiment in comparison with a conventional one.

### DETAILED DESCRIPTION OF THE PREFERRED EMBODIMENTS

Hereinafter, embodiments of a flexible wiring component and a conductive module according to the present invention will be described in detail with reference to the drawings. Note that this invention is not limited by this embodiment.

### Embodiment

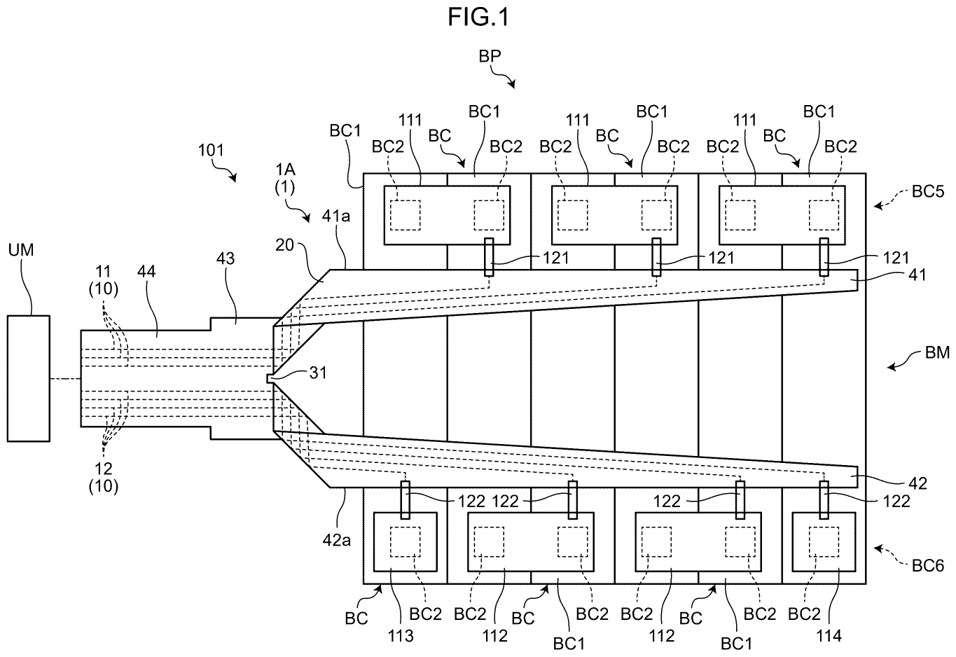

One of embodiments of the flexible wiring component and the conductive module according to the present invention will be described with reference to FIG. 1 to FIG. 5.

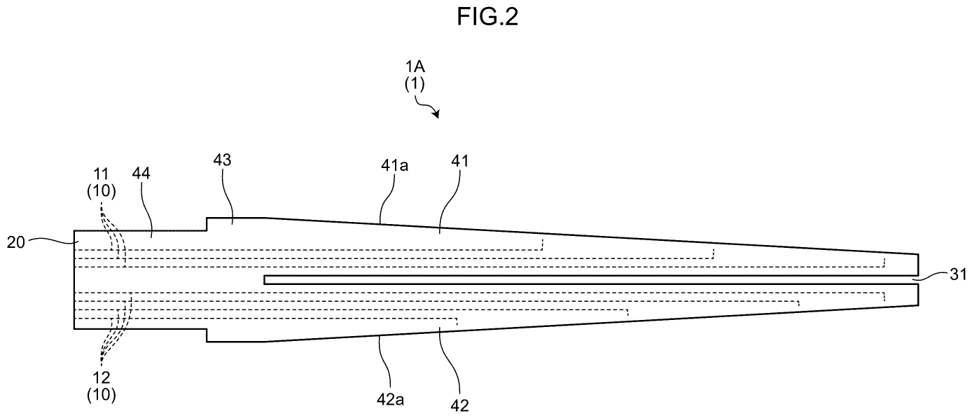

A reference sign 1 in FIG. 1 and FIG. 2 denotes the flexible wiring component of the present embodiment. A reference sign 101 in FIG. 1 denotes a conductive module including the flexible wiring component 1. The conductive module 101 is assembled to a battery module BM in which a plurality of battery cells BC is arranged in one row, and forms a battery pack BP together with the battery module BM (FIG. 1). The battery pack BP is mounted on, for example, a vehicle including a rotary machine as a driving source (such as a battery electric vehicle (BEV) or a hybrid electric vehicle (HEV)), and is used to feed power to the rotary machine. A configuration of the battery module BM in the drawing, such as the number of battery cells BC is simplified for convenience of description.

Each of the battery cells BC includes a cell body BC1 and positive and negative electrode terminals BC2 (FIG. 1). The two electrode terminals BC2 are arranged at an interval in the cell body BC1. In the battery cell BC described here, the two electrode terminals BC2 are arranged at the interval on the same plane in the cell body BC1.

In the battery cell BC described here, the cell body BC1 is formed in a rectangular parallelepiped shape having six outer wall surfaces, and each of the positive and negative electrode terminals BC2 is provided on one of the six outer wall surfaces of the cell body BC1. In the plurality of battery cells BC included in the battery module BM, the cell bodies BC1 adjacent to each other in an array direction are arranged in such a manner that one each of outer wall surfaces thereof face each other. Thus, in the battery cell BC described here, among the six outer wall surfaces of the cell body BC1, the two electrode terminals BC2 are provided on one of the four outer wall surfaces in the array direction of the plurality of battery cells BC. On the one outer wall surface of the cell body BC1, the electrode terminal BC2 serving as the positive electrode is arranged at one end in an orthogonal direction with respect to the array direction of the plurality of battery cells BC, and the electrode terminal BC2 serving as the negative electrode is arranged at the other end in the orthogonal direction.

Each of the positive and negative electrode terminals BC2 may have, for example, a plate shape or a rectangular parallelepiped shape provided on one of the outer wall surfaces of the cell body BC1, or may be a columnar pole protruding from the one outer wall surface of the cell body BC1. In a case of the plate-like or rectangular parallelepiped electrode terminal BC2, a first inter-terminal connection component 111, a second inter-terminal connection component 112, and a total positive electrode connection component 113 or a total negative electrode connection component 114 (described later) are physically and electrically connected to the electrode terminal BC2 by welding or the like. Furthermore, in a case of the electrode terminal BC2 as the pole, since a male screw portion is provided in the electrode terminal BC2, the electrode terminal BC2 is inserted into a through hole of the first inter-terminal connection component 111, the second inter-terminal connection component 112, and the total positive electrode connection component 113 or the total negative electrode connection component 114 (described later), and a female screw member is screwed with the male screw portion of the electrode terminal BC2, whereby the first inter-terminal connection component 111, the second inter-terminal connection component 112, and the total positive electrode connection component 113 or the total negative electrode connection component 114 are physically and electrically connected to the electrode terminal BC2. Here, the rectangular plate-like electrode terminal BC2 is taken as an example.

The battery module BM includes a first electrode terminal group BC5 in which one of the electrode terminals BC2 in each of the battery cells BC is lined up in the array direction of the plurality of battery cells BC, and a second electrode terminal group BC6 in which the other of the electrode terminals BC2 in each of the battery cells BC is lined up in the array direction of the plurality of battery cells BC (FIG. 1).

For example, in the first electrode terminal group BC5, the positive electrode terminals BC2 and the negative electrode terminals BC2 are lined up alternately in the array direction of the plurality of battery cells BC. In this case, in the second electrode terminal group BC6, the positive electrode terminals BC2 and the negative electrode terminals BC2 are lined up alternately in the array direction of the plurality of battery cells BC. For example, in the first electrode terminal group BC5, only the positive electrode terminals BC2 are lined up in the array direction of the plurality of battery cells BC. In this case, in the second electrode terminal group BC6, only the negative electrode terminals BC2 are lined up in the array direction of the plurality of battery cells BC.

Hereinafter, in a case of being simply described as the “array direction”, the array direction refers to the array direction of the plurality of battery cells BC.

A battery monitoring unit UM that monitors a battery state of each of the battery cells BC in the battery module BM is mounted on a vehicle (FIG. 1). The battery module BM and the battery monitoring unit UM are electrically connected by the conductive module 101.

The conductive module 101 includes the first inter-terminal connection component 111, the second inter-terminal connection component 112, the total positive electrode connection component 113, and the total negative electrode connection component 114 in addition to the flexible wiring component 1 (FIG. 1). The first inter-terminal connection component 111, the second inter-terminal connection component 112, the total positive electrode connection component 113, and the total negative electrode connection component 114 are plate-like conductive components made of metal and referred to as bus bars.

The first inter-terminal connection component 111 physically and electrically connects the pair of electrode terminals BC2 adjacent in the array direction in the first electrode terminal group BC5, whereby the pair of electrode terminals BC2 is electrically connected (FIG. 1). The first inter-terminal connection component 111 is provided for every pair of electrode terminals BC2. The second inter-terminal connection component 112 physically and electrically connects the pair of electrode terminals BC2 adjacent in the array direction in the second electrode terminal group BC6, whereby the pair of electrode terminals BC2 is electrically connected (FIG. 1). The second inter-terminal connection component 112 is provided for every pair of electrode terminals BC2.

The total positive electrode connection component 113 is physically and electrically connected to the electrode terminal BC2 serving as the total positive electrode of any one of the first electrode terminal group BC5 or the second electrode terminal group BC6 (FIG. 1). The total negative electrode connection component 114 is physically and electrically connected to the electrode terminal BC2 serving as the total negative electrode of any one of the first electrode terminal group BC5 or the second electrode terminal group BC6 (FIG. 1).

The first electrode terminal group BC5 described here includes a plurality of sets of the pair of electrode terminals BC2 to be electrically connected, and the first inter-terminal connection component 111 is connected to each combination (FIG. 1). On the other hand, the second electrode terminal group BC6 described here includes a plurality of sets of the pair of electrode terminals BC2 to be electrically connected, and the electrode terminal BC2 as the total positive electrode and the electrode terminal BC2 as the total negative electrode (FIG. 1). In the second electrode terminal group BC6, the second inter-terminal connection component 112 is connected to each combination of the pair of electrode terminals BC2, the total positive electrode connection component 113 is connected to the electrode terminal BC2 serving as the total positive electrode, and the total negative electrode connection component 114 is connected to the electrode terminal BC2 serving as the total negative electrode.

The flexible wiring component 1 is a voltage detection line group 10 that electrically connects the battery module BM and the battery monitoring unit UM and that is covered with insulation coating 20, and is formed as a flexible flat wiring main body 1A extending in the array direction (FIG. 1 and FIG. 2). The voltage detection line group 10 includes a plurality of first voltage detection lines 11 that electrically connects the electrode terminals BC2 of the first electrode terminal group BC5 and the battery monitoring unit UM, and a plurality of second voltage detection lines 12 that electrically connects the electrode terminals BC2 of the second electrode terminal group BC6 and the battery monitoring unit UM (FIG. 1 and FIG. 2). For example, the first voltage detection line 11 is provided for each of the first inter-terminal connection components 111 and electrically connects the first inter-terminal connection component 111 and the battery monitoring unit UM. In addition, the second voltage detection line 12 is provided for each of the second inter-terminal connection components 112, and electrically connects the second inter-terminal connection component 112 and the battery monitoring unit UM.

For example, the conductive module 101 includes a first intermediate connection component 121 provided for each of the first voltage detection lines 11 and a second intermediate connection component 122 provided for each of the second voltage detection lines 12 (FIG. 1). The first intermediate connection component 121 and the second intermediate connection component 122 may be, for example, plate-like conductive components (bus bars) made of metal or may be electric wires. The first intermediate connection component 121 is physically and electrically connected to the pair of the first voltage detection line 11 and the first inter-terminal connection component 111 by welding, soldering, or the like. The second intermediate connection component 122 is physically and electrically connected to the pair of the second voltage detection line 12 and the second inter-terminal connection component 112 by welding, soldering, or the like. In this example, the second intermediate connection component 122 is physically and electrically connected to the pair of second voltage detection line 12 and total positive electrode connection component 113 by welding, soldering, or the like, and the second intermediate connection component 122 is physically and electrically connected to the pair of second voltage detection line 12 and the total negative electrode connection component 114 by welding, soldering, or the like.

Here, the same components are used for the first intermediate connection component 121 and the second intermediate connection component 122.

The wiring main body 1A described here is a flexible printed circuit (FPC), and is formed of various films (base film and cover film) in which the voltage detection lines (first voltage detection lines 11 and second voltage detection lines 12) of the voltage detection line group 10 are formed by conductor patterns, and on which the insulation coating 20 is formed flat with flexibility. In the wiring main body 1A, the conductor patterns are formed on at least one (base film) of the various films. The conductor pattern is covered with the insulation coating 20, and a place to be an electrical contact with other components such as the first intermediate connection component 121 and the second intermediate connection component 122 is exposed, for example.

The wiring main body 1A has a linear or rectangular slit 31 cut out in the array direction from one end to the other end in the array direction (FIG. 1 and FIG. 2). The wiring main body 1A includes a first branch wiring portion 41 which extends in the array direction on a side of the first electrode terminal group BC5 compared to the slit 31 and in which the plurality of first voltage detection lines 11 is routed, and a second branch wiring portion 42 which extends in the array direction on a side of the second electrode terminal group BC6 compared to the slit 31 and in which the plurality of second voltage detection lines 12 is routed (FIG. 1 and FIG. 2).

Furthermore, the wiring main body 1A includes a coupling wiring portion 43 that couples the first branch wiring portion 41 and the second branch wiring portion 42 on a side of the other end in the array direction, and that electrically connects the plurality of first voltage detection lines 11 and the plurality of second voltage detection lines 12 to the battery monitoring unit UM (FIG. 1 and FIG. 2). The coupling wiring portion 43 electrically connects the plurality of first voltage detection lines 11 connected from the first branch wiring portion 41 and the plurality of second voltage detection lines 12 connected from the second branch wiring portion 42 to the battery monitoring unit UM.

Furthermore, the wiring main body 1A includes a unit connection portion 44 that protrudes from the side of the other end in the array direction of the coupling wiring portion 43 to a side opposite to the first branch wiring portion 41 and the second branch wiring portion 42 in the array direction, and that electrically connects the plurality of first voltage detection lines 11 and the plurality of second voltage detection lines 12 to a connector (not illustrated) on a side of the battery monitoring unit UM (FIG. 1 and FIG. 2). The unit connection portion 44 electrically connects the plurality of first voltage detection lines 11 and the plurality of second voltage detection lines 12 connected from the coupling wiring portion 43 to the connector on the side of the battery monitoring unit UM. The unit connection portion 44 described here is formed in a rectangular shape.

The first branch wiring portion 41 includes a first inclined side portion 41a that is a side portion on the side of the first electrode terminal group BC5, the side portion being continuous with a side portion on the side of the first electrode terminal group BC5 in the coupling wiring portion 43, and that gradually approaches the slit 31 from the side of the other end in the array direction toward the side of the one end in the array direction (FIG. 1 and FIG. 2). The second branch wiring portion 42 includes a second inclined side portion 42a that is a side portion on the side of the second electrode terminal group BC6, the side portion being continuous with a side portion on the side of the second electrode terminal group BC6 in the coupling wiring portion 43, and that gradually approaches the slit 31 from the side of the other end in the array direction toward the side of the one end in the array direction (FIG. 1 and FIG. 2). The first inclined side portion 41a and the second inclined side portion 42a are inclined at the same angle in the array direction.

Here, the first inclined side portion 41a is arranged on the side of the slit 31 compared to an end portion of the coupling wiring portion 43 on the side of the first electrode terminal group BC5 in a facing arrangement direction of the first branch wiring portion 41 and the second branch wiring portion 42. In addition, the second inclined side portion 42a is arranged on the side of the slit 31 compared to an end portion of the coupling wiring portion 43 on the side of the second electrode terminal group BC6 in the facing arrangement direction of the first branch wiring portion 41 and the second branch wiring portion 42. For example, the coupling wiring portion 43 described here is formed in a rectangular shape provided with two side portions in the array direction. Thus, the first inclined side portion 41a described here is a side portion continuous with the side portion of the coupling wiring portion 43 on the side of the first electrode terminal group BC5, and is arranged on the side of the slit 31 compared to the side portion of the coupling wiring portion 43 in the facing arrangement direction of the first branch wiring portion 41 and the second branch wiring portion 42. Furthermore, the second inclined side portion 42a described here is a side portion continuous with the side portion of the coupling wiring portion 43 on the side of the second electrode terminal group BC6, and is arranged on the side of the slit 31 compared to the side portion of the coupling wiring portion 43 in the facing arrangement direction of the first branch wiring portion 41 and the second branch wiring portion 42.

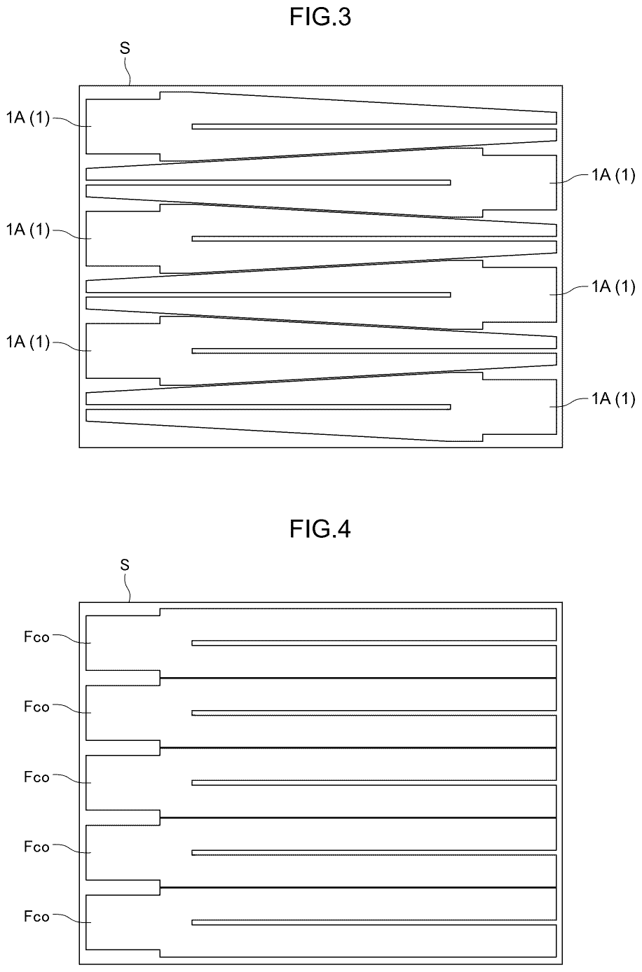

The flexible wiring component 1 is formed by die cutting of a plurality of the wiring main bodies 1A having this shape from one sheet-like base material (such as a stack of a base film on which a plurality of the voltage detection line groups 10 is formed and a cover film) S (FIG. 3). For example, here, the six wiring main bodies 1A can be cut out from the one base material S. On the other hand, in a case of a conventional flexible wiring component Fco having a rectangular outer peripheral edge, only the five flexible wiring components Fco can be cut out from the base material S (FIG. 4). As described above, since the more wiring main bodies 1A can be cut out from the one sheet-like base material S in the flexible wiring component 1 of the present embodiment than in the conventional case, a yield is improved.

The flexible wiring component 1 is die cut from the base material S, processed as follows, and then assembled to the battery module BM. In the flexible wiring component 1, the first branch wiring portion 41 is bent twice from a root on a side of the coupling wiring portion 43, and is routed in a manner close to the first electrode terminal group BC5 (FIG. 1 and FIG. 2). Then, the second branch wiring portion 42 is bent twice from a root on the side of the coupling wiring portion 43, and is routed in a manner close to the second electrode terminal group BC6 (FIG. 1 and FIG. 2).

As described above, in the flexible wiring component 1, a positional relationship between the first branch wiring portion 41 and the second branch wiring portion 42 can be adjusted in accordance with an interval between the first electrode terminal group BC5 and the second electrode terminal group BC6 after the die cutting. Thus, the flexible wiring component 1 can improve the yield at the time of the die cutting from the base material S.

For example, in the conductive module 101, the first intermediate connection component 121, the second intermediate connection component 122, the first inter-terminal connection component 111, the second inter-terminal connection component 112, the total positive electrode connection component 113, and the total negative electrode connection component 114 are connected to the processed flexible wiring component 1 in advance. Then, the conductive module 101 to which these components are connected is assembled to the battery module BM.

As described above, in the flexible wiring component 1 and the conductive module 101 of the present embodiment, since the first branch wiring portion 41 and the second branch wiring portion 42 have a tapered shape made close to the side of the slit 31, it is possible to improve the yield of when the wiring main body 1A is die cut from the one sheet-like base material S. Thus, costs of the flexible wiring component 1 and the conductive module 101 can be reduced.

Here, the flexible wiring component 1 is desirably assembled to the battery module BM after being subjected to the following processing after being die cut from the base material S. In the flexible wiring component 1 described here, the first branch wiring portion 41 is bent twice from the root on the side of the coupling wiring portion 43 in such a manner as to cause the first inclined side portion 41a to be in the array direction, and is routed in a manner close to the first electrode terminal group BC5 (FIG. 1 and FIG. 2). Then, the second branch wiring portion 42 is bent twice from the root on the side of the coupling wiring portion 43 in such a manner as to cause the second inclined side portion 42a to be in the array direction, and is routed in a manner close to the second electrode terminal group BC6 (FIG. 1 and FIG. 2).

As a result, in the flexible wiring component 1, the intervals between the first branch wiring portion 41 and all the electrode terminals BC2 of the first electrode terminal group BC5 can be equalized, and intervals between the second branch wiring portion 42 and all the electrode terminals BC2 of the second electrode terminal group BC6 can be equalized. Thus, in the conductive module 101, since all the first intermediate connection components 121 and the second intermediate connection components 122 can be unified to the same components, it is possible to reduce the cost.

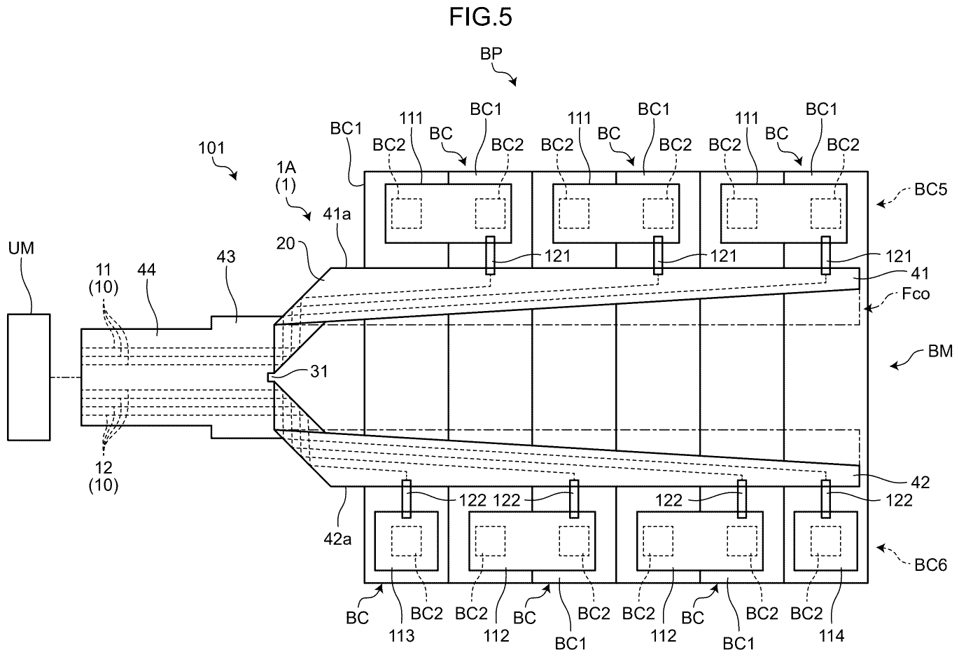

In addition, in the flexible wiring component 1, since the first branch wiring portion 41 and the second branch wiring portion 42 are tapered, it is possible to make an interval between the first branch wiring portion 41 and the second branch wiring portion 42 larger than that of the conventional flexible wiring component Fco (two-dot chain line) by making the first inclined side portion 41a be in the array direction and making the second inclined side portion 42a be in the array direction (FIG. 5). As described above, in the flexible wiring component 1 and the conductive module 101 of the present embodiment, the mounting area of the battery module BM can be reduced as compared with the conventional case.

In the flexible wiring component and the conductive module according to the present embodiment, since a first branch wiring portion and a second branch wiring portion have a tapered shape made close to a slit side, it is possible to improve the yield of when a wiring main body is die cut from one sheet-like base material.

Although the invention has been described with respect to specific embodiments for a complete and clear disclosure, the appended claims are not to be thus limited but are to be construed as embodying all modifications and alternative constructions that may occur to one skilled in the art that fairly fall within the basic teaching herein set forth.

What is claimed is:

1. A flexible wiring component that is a voltage detection line group electrically connecting a battery module and a battery monitoring unit and covered with insulation coating, a plurality of battery cells being arrayed in a row in the battery module, the battery monitoring unit monitoring a battery state of each of the battery cells, the flexible wiring component being formed as a flexible flat wiring main body extending in an array direction of the plurality of battery cells, wherein
one each of positive and negative electrode terminals are provided at an interval in a cell body in each of the battery cells,
the battery module includes a first electrode terminal group in which one of the electrode terminals in each of the battery cells is lined up in the array direction, and a second electrode terminal group in which another one of the electrode terminals in each of the battery cells is lined up in the array direction,
the voltage detection line group includes a plurality of first voltage detection lines electrically connecting the electrode terminals of the first electrode terminal group and the battery monitoring unit, and a plurality of second voltage detection lines electrically connecting the electrode terminals of the second electrode terminal group and the battery monitoring unit,
the wiring main body includes a linear or rectangular slit cut out in the array direction from one end to another end in the array direction, a first branch wiring portion that extends in the array direction on a side of the first electrode terminal group compared to the slit, and in which the plurality of first voltage detection lines is routed, a second branch wiring portion that extends in the array direction on a side of the second electrode terminal group compared to the slit and in which the plurality of second voltage detection lines is arranged, and a coupling wiring portion that couples the first branch wiring portion and the second branch wiring portion on a side of the other end in the array direction and electrically connects the plurality of first voltage detection lines and the plurality of second voltage detection lines to the battery monitoring unit,
the first branch wiring portion includes a first inclined side portion that is a side portion on a side of the first electrode terminal group, the side portion being continuous with an end portion on the side of the first electrode terminal group in the coupling wiring portion, and that gradually approaches the slit from the side of the other end in the array direction toward the side of the one end in the array direction,
the second branch wiring portion includes a second inclined side portion that is a side portion on a side of the second electrode terminal group, the side portion being continuous with an end portion on the side of the second electrode terminal group in the coupling wiring portion, and that gradually approaches the slit from the side of the other end in the array direction toward the side of the one end in the array direction, and
the first inclined side portion and the second inclined side portion are inclined at a same angle in the array direction.

2. The flexible wiring component according to claim 1, wherein
the first branch wiring portion is bent twice from a root on a side of the coupling wiring portion and routed in a manner close to the first electrode terminal group, and
the second branch wiring portion is bent twice from a root on the side of the coupling wiring portion and routed in a manner close to the second electrode terminal group.

3. The flexible wiring component according to claim 1, wherein
the first branch wiring portion is bent twice from a root on a side of the coupling wiring portion in such a manner that the first inclined side portion is in the array direction, and is routed in a manner close to the first electrode terminal group, and
the second branch wiring portion is bent twice from a root on the side of the coupling wiring portion in such a manner that the second inclined side portion is in the array direction, and is routed in a manner close to the second electrode terminal group.

4. The flexible wiring component according to claim 1, wherein
the wiring main body includes a unit connection portion that protrudes from the side of the other end of the coupling wiring portion in the array direction to a side opposite to the first branch wiring portion and the second branch wiring portion in the array direction, and electrically connects the plurality of first voltage detection lines and the plurality of second voltage detection lines to a connector on a side of the battery monitoring unit.

5. The flexible wiring component according to claim 2, wherein
the wiring main body includes a unit connection portion that protrudes from the side of the other end of the coupling wiring portion in the array direction to a side opposite to the first branch wiring portion and the second branch wiring portion in the array direction, and electrically connects the plurality of first voltage detection lines and the plurality of second voltage detection lines to a connector on a side of the battery monitoring unit.

6. The flexible wiring component according to claim 3, wherein
the wiring main body includes a unit connection portion that protrudes from the side of the other end of the coupling wiring portion in the array direction to a side opposite to the first branch wiring portion and the second branch wiring portion in the array direction, and electrically connects the plurality of first voltage detection lines and the plurality of second voltage detection lines to a connector on a side of the battery monitoring unit.

7. The flexible wiring component according to claim 1, wherein
the wiring main body is a flexible printed circuit.

8. The flexible wiring component according to claim 2, wherein
the wiring main body is a flexible printed circuit.

9. The flexible wiring component according to claim 3, wherein
the wiring main body is a flexible printed circuit.

10. A conductive module comprising:
a flexible wiring component;
a first inter-terminal connection component;
a second inter-terminal connection component;
a first intermediate connection component; and
a second intermediate connection component, wherein
the flexible wiring component is a voltage detection line group electrically connecting a battery module and a battery monitoring unit and covered with insulation coating, a plurality of battery cells being arrayed in a row in the battery module, the battery monitoring unit monitoring a battery state of each of the battery cells, the flexible wiring component being formed as a flexible flat wiring main body extending in an array direction of the plurality of battery cells,
one each of positive and negative electrode terminals are provided at an interval in a cell body in each of the battery cells,
the battery module includes a first electrode terminal group in which one of the electrode terminals in each of the battery cells is lined up in the array direction, and a second electrode terminal group in which another one of the electrode terminals in each of the battery cells is lined up in the array direction,
the first inter-terminal connection component is provided for every pair of the electrode terminals adjacent in the array direction in the first electrode terminal group and electrically connects the pair of electrode terminals,
the second inter-terminal connection component is provided for every pair of the electrode terminals adjacent in the array direction in the second electrode terminal group and electrically connects the pair of electrode terminals,
the voltage detection line group includes a first voltage detection line that is provided for each of the first inter-terminal connection components and electrically connects the first inter-terminal connection component and the battery monitoring unit, and a second voltage detection line that is provided for each of the second inter-terminal connection components and that electrically connects the second inter-terminal connection component and the battery monitoring unit,
the first intermediate connection component is provided for each of the first voltage detection lines, and is physically and electrically connected to a pair of the first voltage detection line and the first inter-terminal connection component,
the second intermediate connection component is provided for each of the second voltage detection lines, and is physically and electrically connected to a pair of the second voltage detection line and the second inter-terminal connection component,
the wiring main body includes a linear or rectangular slit cut out in the array direction from one end to another end in the array direction, a first branch wiring portion that extends in the array direction on a side of the first electrode terminal group compared to the slit, and in which a plurality of the first voltage detection lines is routed, a second branch wiring portion that extends in the array direction on a side of the second electrode terminal group compared to the slit and in which a plurality of the second voltage detection lines is routed, and a coupling wiring portion that couples the first branch wiring portion and the second branch wiring portion on a side of the other end in the array direction and electrically connects the plurality of first voltage detection lines and the plurality of second voltage detection lines to the battery monitoring unit,
the first branch wiring portion includes a first inclined side portion that is a side portion on a side of the first electrode terminal group, the side portion being continuous with an end portion on the side of the first electrode terminal group in the coupling wiring portion, and that gradually approaches the slit from the side of the other end in the array direction toward a side of the one end in the array direction,
the second branch wiring portion includes a second inclined side portion that is a side portion on a side of the second electrode terminal group, the side portion being continuous with an end portion on the side of the second electrode terminal group in the coupling wiring portion, and that gradually approaches the slit from the side of the other end in the array direction toward the side of the one end in the array direction, and
the first inclined side portion and the second inclined side portion are inclined at a same angle in the array direction.
